(19) United States
(12) Patent Application Publication
(10) Pub. No.: US 2024/0121964 A1
(43) Pub. Date: Apr. 11, 2024

(54) ALD VS PVD IGZO CHANNEL AND ALOX CHANNEL PASSIVATION IN A 3D NAND VERTICAL WORDLINE DRIVER

(71) Applicant: Intel NDTM US LLC, Santa Clara, CA (US)

(72) Inventors: Jessica Sevanne KACHIAN, Half Moon Bay, CA (US); Jose CRUZ-CAMPA, Albuquerque, NM (US)

(21) Appl. No.: 18/542,337

(22) Filed: Dec. 15, 2023

(51) Int. Cl. H10B 43/40; H10B 41/41

(52) U.S. Cl. CPC H10B 43/40; H10B 41/41; G11C 16/08

(57) ABSTRACT

ALD versus PVD IGZO Channel and AlOx channel passivation in a vertical wordline driver. A pillar is formed in a stacked layer semiconductor structure including a source layer, wherein forming the pillar exposes layers in the semiconductor structure and exposes a portion of the source layer at the bottom of the pillar. A gate oxide film is formed over exposed layers in the semiconductor structure and over the exposed portion of the source layer. A sacrificial silicon liner is formed over the gate oxide, and subsequently both the gate oxide and the sacrificial silicon liner are removed from the pillar bottom in an anisotropic dry etch (“punch”) process that exposes the source layer. The sacrificial silicon liner is stripped from the gate oxide wall, and a film of IGZO is formed over the gate oxide film and a portion of the source layer, and a high-κ channel passivation deposition process follows to form a film of a high-κ material over the film of IGZO to form a hermetically sealed IGZO channel contained within a vertical wordline driver supporting a drive voltage of at least 10 volts.

### CROSS-REFERENCE TO RELATED APPLICATION

The subject matter disclosed herein is related to subject matter disclosed in U.S. patent application Ser. No. 18/188,391, entitled VERTICAL WORDLINE DRIVER STRUCTURES AND METHODS, filed on Mar. 22, 2023. The present application and the '391 application are commonly assigned to Intel Corporation.

### BACKGROUND INFORMATION

A flash memory device may comprise a memory array that includes a large number of non-volatile memory cells arranged in arrays of rows and columns. In recent years, vertical memory, such as three-dimensional (3D) memory, has been developed in various forms, such as NAND, NOR, cross-point, or the like. A 3D flash memory array may include a plurality of memory cells stacked over one another. Each group of memory cells may share a plurality of access lines, known as wordlines and bitlines.

In NAND memory technology, particularly in 3D NAND memory technology, connection between wordline driver transistors and respective wordlines is an important architecture decision, which affects the 3D NAND die area, die performance and system metrics. Wordline driver transistors need to support high voltages and break down condition and occupy a significant area of the 3D NAND die. The memory tile-based architecture on 3D NAND further increases the total wordline driver area in the die. In general, disposition of the wordline driver transistors affects the contact area availability and block height dimensions in a flash memory device.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIG. 1 is a block diagram of an example of a system that stores data in Non-volatile (NV) media;

FIG. 2 is a block diagram of an example of system including a three-dimensional (3D) memory device structure;

FIG. 3a is a diagram illustrating elevation and plan cross-section views of a transistor structure comprising a gate all around (GAA) thin film transistor (TFT) structure, according to a first embodiment;

FIG. 3b is a diagram illustrating cross-section views of a transistor structure comprising a double gate, according to a second embodiment;

FIGS. 4a-4h show elevation cross-section views of a semiconductor structure after respective steps in a fabrication process, according to one embodiment;

FIGS. 5a, 5b, and 5c show elevation cross-section views of a semiconductor structure after anisotropic gate oxide punch etch, sacrificial silicon liner wet strip, and channel and subsequent channel passivation deposition process steps, respectively, according to one embodiment;

FIG. 6 is a flowchart illustrating steps performed to obtain the semiconductor structure shown in FIG. 4a;

FIG. 7 is a flowchart illustrating process operations using high-k channel passivation deposition to achieve (within back-end-of-line (BEOL) temperature (T) constraints) a hermetically sealed IGZO channel of target/goal composition needed for super high voltage (SHV) operation employing a PVD-based flow (i.e., IGZO channel and high-κ channel passivation deposited by PVD), according to one embodiment;

FIG. 8 is a flowchart illustrating process operations including high-k channel passivation deposition and collectively achieving (within BEOL temperature constraints) a hermetically sealed IGZO channel of target/goal composition needed for SHV operation employing a ALD-based flow (i.e., IGZO channel and high-κ channel passivation deposited by ALD), according to one embodiment;

FIG. 9 is a flowchart illustrating operations performed during steps to obtain the semiconductor structures shown in FIGS. 4b-4h;

FIG. 10a is a diagram illustrating elevation cross-section views of a semiconductor structure including two GAA TFT devices (vertical wordline drivers) having a first alternative configuration, according to one embodiment;

FIG. 10b is a diagram illustrating an elevation cross-section view of the semiconductor structure of FIG. 10a within a wider field of view (relative to FIG. 10a) to show further details of the vertical wordline drivers connecting to respective wordlines within the staircase, according to one embodiment;

FIG. 10c is a diagram illustrating a plan cross-section view and the cross-section view of FIG. 10b;

FIG. 11a is a diagram illustrating elevation cross-section views of a semiconductor structure including two GAA TFT devices (vertical wordline drivers) having a second alternative configuration, according to one embodiment;

FIG. 11b is a diagram illustrating an elevation cross-section view of the semiconductor structure of FIG. 11a within a wider field of view (relative to FIG. 11a) to show further details of the vertical wordline drivers connecting to respective wordlines within the staircase, according to one embodiment;

FIG. 12 is a diagram illustrating an elevation cross-section view of a semiconductor structure containing vertical wordline drivers employing the GAA TFT device structure of FIG. 3 and connecting to respective wordlines, according to one embodiment;

FIG. 13a is a diagram illustrating elevation cross-section views of a semiconductor structure including two GAA TFT devices (vertical wordline drivers) having a third alternative configuration, according to one embodiment;

FIG. 13b is a diagram illustrating an elevation cross-section view of the semiconductor structure of FIG. 13a within a wider field of view (relative to FIG. 13a) to show further details of the vertical wordline drivers connecting to respective wordlines within the staircase, according to one embodiment; and

FIG. 14 is a diagram illustrating a 3D view of an abstracted memory device in which aspect of the embodiments described and illustrated herein may be implemented, according to one embodiment.

### DETAILED DESCRIPTION

Embodiments of ALD (Atomic Layer Deposition) versus PVD (Physical Vapor Deposition) IGZO Channel and AlOx channel passivation in a vertical wordline driver are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

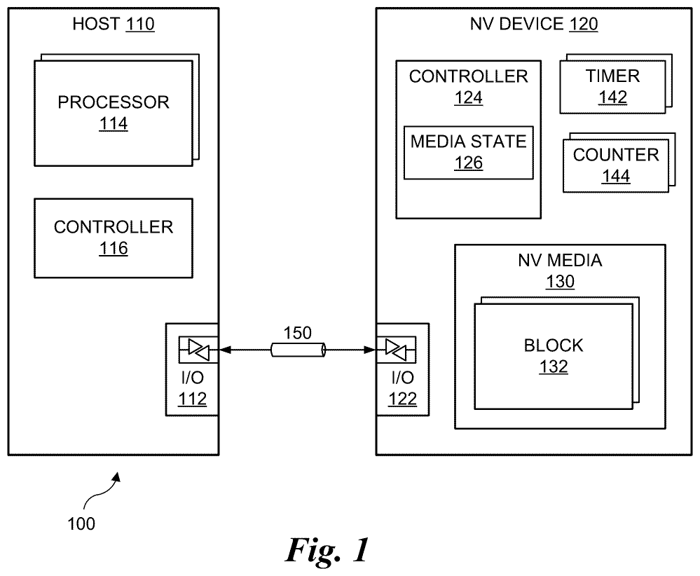

FIG. 1 is a block diagram of an example of a system that stores data in Non-volatile (NV) media. System 100 includes host 110 coupled to NV device 120. Host 110 represents a computing device. Host 110 includes I/O (input/output) 112, which represents hardware to interconnect with NV device 120. NV device 120 includes I/O 122 which corresponds to I/O 112. I/O 122 represents hardware to interconnect with host 110.

Host 110 provides a hardware platform to operate NV device 120. Host 110 includes one or more processors 114 to perform the operations of host 110. Processor 114 executes a host operating system (OS) that provides a software platform for the operation of NV device 120. The hardware platform provides hardware resources to interface with NV device 120 including transceiver hardware to perform access to the device. The software platform includes control software to execute other software elements such as applications or other agents that execute under the OS and create requests to access NV device 120.

I/O 112 and I/O 122 interconnect through one or more signal lines 150. Signal lines 150 typically include multiple separate lines and can be considered one or more buses to connect host 110 to NV device 120. Host 110 can send a host read command over signal line 150 to NV device 120. In response to the read command, NV device 120 services the request out of a transient Vt state, in accordance with any example provided.

In one example, host 110 includes controller 116. Controller 116 represents a memory controller or storage controller. In one example, controller 116 is integrated with processor 114. In one example, controller 116 is separate from processor 114. Controller 116 enables host 110 to manage access to NV device 120. In response to host operations by processor 114 that request access to data on NV device 120, controller 116 provides access to NV device 120. Controller 116 can represent hardware and firmware elements of host 110 to enable interaction with NV device 120.

NV device 120 includes controller 124, which represents a storage controller at the side of the storage device, which is separate from controller 116 of host 110. Controller 116 of host 110 represents components of the host system. Controller 124 represents components of the storage device or memory device into which the NV media is incorporated. Controller 124 receives commands send from host 110 and determines how to service the command or request from the host. Controller 124 performs operations to access (e.g., read or write) NV media 130 in response to the host command.

NV media 130 represents a nonvolatile storage media of NV device 120. In one example, NV media 130 includes three-dimensional (3D) NAND (not AND) memory cells. In one example, NV media 130 includes 3D NOR memory cells. In one example, NV media 130 includes 3D crosspoint memory cells.

NV media 130 includes bitcells or memory cells organized as blocks 132. A block of memory refers to a portion of NV media 130 that is jointly charged or activated for an access operation. In one example, blocks 132 are subdivided as subblocks. In one example, a block refers to bitcells that share a select gate line. In one example, multiple subblocks share a select gate (e.g., a common select gate source (SGS) or a common select gate drain (SGD)) connector.

In one example, a block refers to an erase unit, or a unit size of NV media 130 that is erased together and monitored by controller 124 for number of writes. In one example, NV media 130 includes single level cell (SLC) and multilevel cell (MLC) media. For example, NV media 130 can include SLC and QLC (quad level cell) or SLC and TLC (triple level cell) bitcells. The block size could be different depending on the media type.

In one example, controller 124 is an ASIC (application specific integrated circuit) that controls operation of NV device 120. In one example, controller 124 is a CPU (central processing unit) core or processor device on NV device 120. In one example, NV device 120 represents an SSD and controller 124 controls multiple NV media dies or NV media chips integrated into the SSD. In one example, NV device 120 represents a module or PCB (printed circuit board) that includes multiple NV media dies or NV media chips integrated onto it and controller 124 controls the NV media dies of the module. In one example, controller 124 executes firmware to manage NV device 120. In one example, controller 124 executes firmware to manage NV device 120, including firmware to control the servicing of a read command based on whether the NV media is in thermal equilibrium.

In one example, controller 124 manages Vt state detection and read command servicing based on idle time or delay between consecutive read commands. In one example, controller 124 monitors one or more media states 126. Media state 126 represents a state of a portion of memory (such as a block) and can determine how to access the media based on media state 126. For example, if media state 126 indicates that a target block is in a stable state, controller 124 can first issue a dummy read prior to accessing the target block. In one example NV media devices 120 may include one or more timers 142 and counters 144.

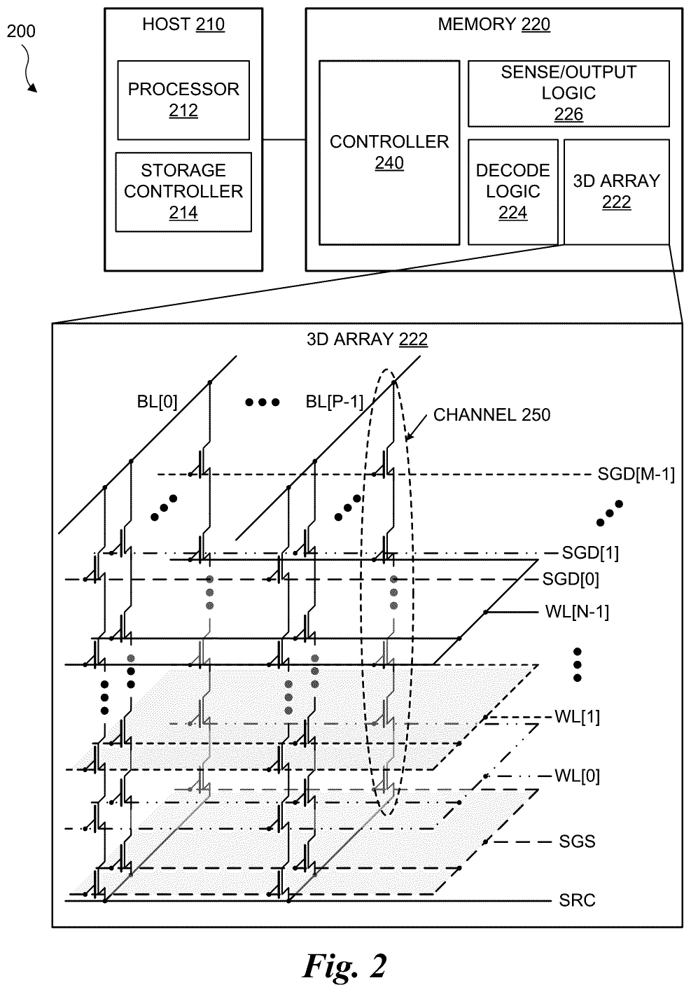

FIG. 2 is a block diagram of an example system illustrating further details of a 3D memory device structure. System 200 represents a computing device that includes a 3D memory. Host 210 represents a hardware platform that performs operations to control the functions of system 200. Host 210 includes processor 212, which is a host processor that executes the operations of the host. In one example, processor 212 is a single-core processor. In one example, processor 212 is a multicore processor device. Processor 212 can be a general-purpose processor that executes a host operating system or a software platform for system 200. In one example, processor 212 is an application specific processor, a graphics processor, a peripheral processor, or other controller or processing unit on host 210. Processor 212 executes multiple agents or software programs (not specifically shown). The agents can be standalone programs and/or threads, processes, software modules, or other code and data to be operated on by processor 212.

During execution of operations by processor 212, an agent executed by the processor can request data and/or code that is not stored at host 210 (e.g., in a cache or main memory), and therefore should be obtained from memory 220. Storage controller 214 generates and processes memory access commands to memory 220 to perform the memory access. Storage controller 214 represents a circuit or logic or processor that manages access to memory 220. In one example, storage controller 214 is part of host 210. In one example, storage controller 214 is part of processor 212. In one example, storage controller 214 is integrated on a common substrate with processor 212. In one example, storage controller 214 separate chip from processor 212, and can be integrated in a multichip package (MCP) with processor 212.

Memory 220 includes controller 240, which represents a controller at the memory or storage device to process and service commands from storage controller 214. In one example, controller 240 represents a controller for a memory device. In one example, controller 240 represents a controller for a memory module. Memory 220 includes 3D array 222. In one example, 3D array 222 includes NAND memory blocks. In one example, 3D array 222 includes QLC NAND memory blocks.

As illustrated, bitlines (BL) intersect the planes of the tiers of wordlines (WL). As an example, each wordline WL[0:(N−1)] is a tier. There can be P bitlines (BL[0:(P−1)]). In one example, 3D array 222 is also divided into subblocks through SGD[0:(M−1)], which divide each wordline into separate segments within a tier or within a plane of wordlines. Alternatively, SGS can be subdivided to provide subblocks. In such a configuration, whereas SGS is shown to apply to multiple SGD lines, there could be multiple SGS lines to a single SGD line. SRC represents a common source.

Channel 250 represents a vertical channel of the 3D array. The channel refers to a vertical stack of bitcells that can be charged through a channel connector. In one example, the channels couple to the bitline. It will be understood that there can be spatial dependencies in the stable Vt state of a channel. For example, the flow of charge carriers in the channel can be different at the different ends of the channels. Thus, blocks with specific wordlines may show worse degradation than others. The operation of controller 240 to mitigate read disturb due to stable Vt in the channel can be set by thresholds and operation that mitigates the most sensitive of the wordlines.

Each label, WL[0], WL[1], SGD[0], and so forth, indicates a select signal provided by control logic of decode logic 224, or a select signal provided by control logic of sense/output logic 226. In one example, decode logic 224 includes selection logic to select each of the signal lines illustrated. In one example, sense/output logic 226 enables the sensing of the contents of bitcells of 3D array 222, for either a read operation or to write a value back to the array. The output can be for a read operation to send data back to host 210. A write operation would include writing to a buffer to apply the values to the array.

It will be understood that a signal line in 3D array 222 is a wire or trace or other conductor that provides charge from a driver to the various elements or components. A driver circuit decode logic 224 provides the charge to charge up each signal line to the desired voltage for the desired operation. Each signal line can have an associated voltage level associated with certain operations. For example, each wordline can have a select voltage and a deselect voltage to indicate, respectively, wordlines that are selected for an operation and wordlines that are not selected for an operation.

In 3D array 222, it will be understood that the length of the wordlines can be substantial. In one example, the number of tiers of wordlines is on the order of tens or dozens of wordlines (e.g., N=28, 32, 36, 70, or more). In one example, the number of subblocks is on the order of ones or tens (e.g., M=8, 76, or more). Typically, the number of bitlines in 3D array 222 will be on the order of hundreds to thousands (e.g., P=2K). Thus, in one example, each bitline is relatively short compared to the length of the wordlines.

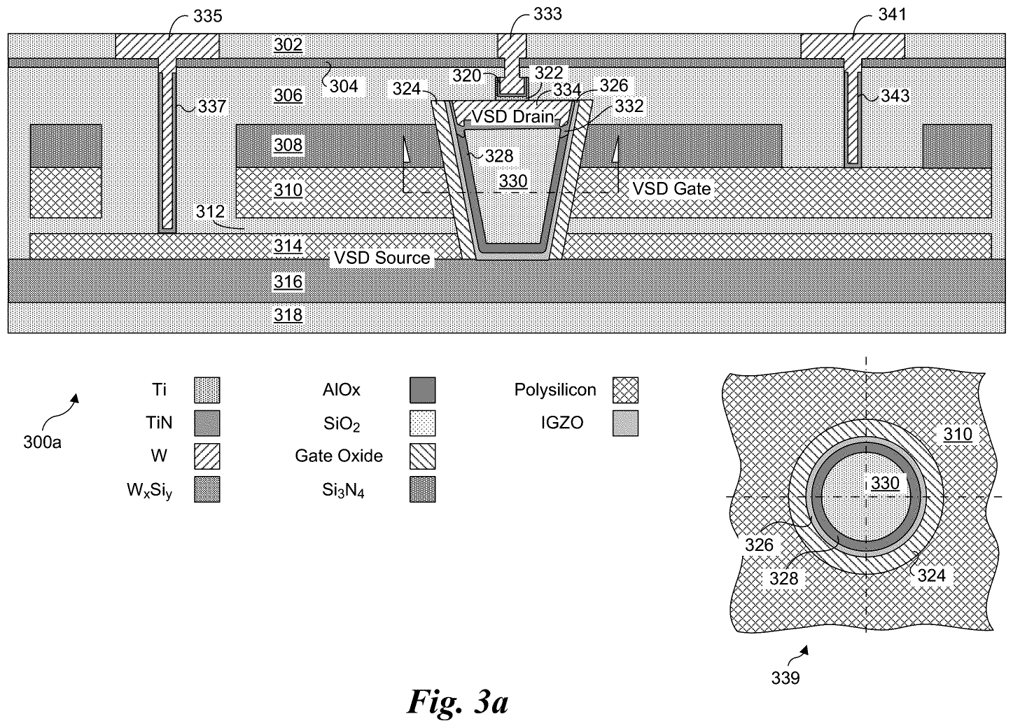

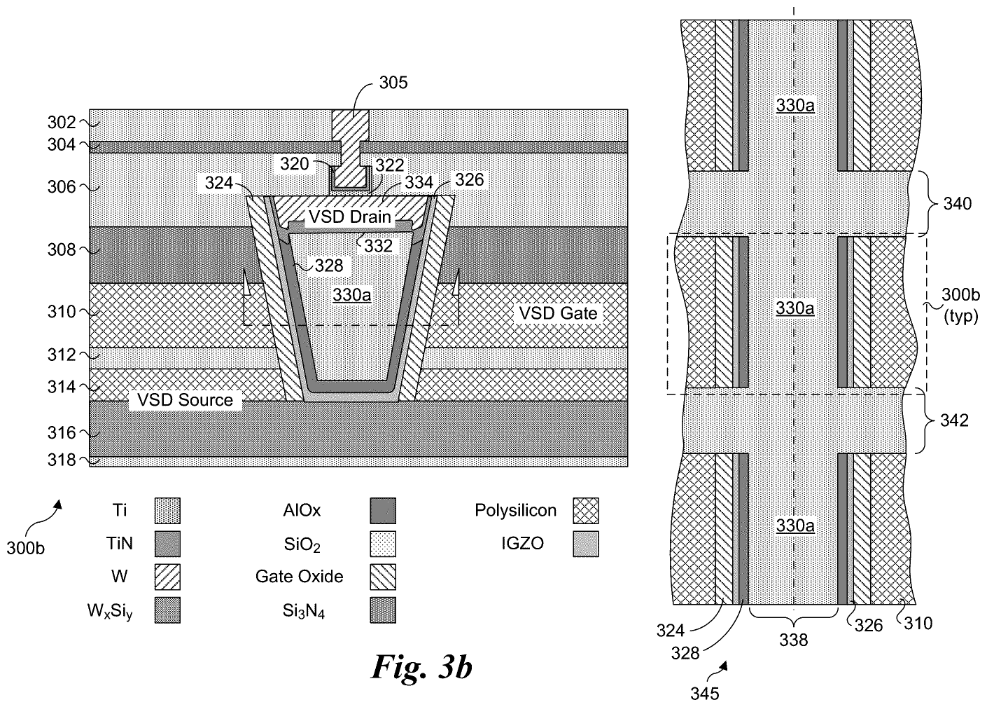

FIG. 3a shows a transistor structure 300a, according to one embodiment. Structure 300a comprises a gate all around (GAA) thin film transistor (TFT) device based on a p-type polysilicon gate, an amorphous IGZO (Indium Gallium Zinc Oxide) channel, an AlOx (aluminum oxide) liner (channel passivation), a low-temperature SiOx gate oxide, and TiN/W (titanium nitride/tungsten) contacts. In one embodiment, an existing poly-Si gate in a conventional 3D NAND structure is used. Optionally, a high workfunction metal replacement gate/multi-gate may be used. An amorphous-IGZO (wide bandgap) oxide semiconductor channel is deposited using physical vapor deposition (PVD) or atomic layer deposition (ALD) in a thickness range of 4-20 nm using workflows described in detail below. An aluminum oxide dielectric channel liner (channel passivation) is deposited under specified conditions with low H content and below a critical thickness in order to ensure positive device Vₜ. In one embodiment the structure employs conventional low-temperature oxide (SiOx) gapfill, and conventional TiN/W contacts.

The layers in structure 300a, which depicts an isolated transistor, include a silicon oxide (SiO₂) layer 302, silicon nitride (SiN, e.g., Si₃N₄) layer 304, an SiO₂ layer 306, a silicon nitride layer 308, a polysilicon layer 310 (transistor gate), an SiO₂ layer 312, a polysilicon layer 314 (part of the transistor source), a WₓSi_{y} (e.g., tungsten silicide (W₅Si₃)) layer 316 (part of the transistor source), and an SiO₂ layer 318. The transistor structure comprises a pillar having an inverted conical frustum shape and including a SiOx gate oxide 324 outer wall, an amorphous IGZO channel 326, an aluminum oxide (AlOx, such as Al₂O₃) channel liner (channel passivation) 328, and an SiO₂ fill 330. FIG. 3a shows that the TiN layer 332 (part of the transistor drain) is located within the pillar and makes physical contact with the IGZO channel 326, AlOx channel liner/passivation 328, and SiO₂ fill 330 beneath it as well as with the W 334 (part of the transistor drain) above it. Contact to the transistor drain metal is facilitated by a lined W plug 333, where the TiN liner 320 beneath the W plug 333 is above and in physical contact with a Ti liner 322 that makes physical contact with the W 334 (part of the transistor drain) within the pillar. Contact to the transistor source is achieved through a W plug 335 that is lined with TiN 337, which physically contacts the underlying polysilicon layer 314 (part of the transistor source) that is in physical contact with the WₓSi_{y} layer 316 (part of the transistor source). Contact to the polysilicon transistor gate (polysilicon layer 310) is achieved through a W plug 341 that is lined with TiN 343, which physically contacts the underlying polysilicon transistor gate 310.

As shown in the cross-section detail 339, the cross-section of the structure including the gate stack in one embodiment is circular; the diameter of the gate oxide 324 outer wall, amorphous IGZO channel 326, AlOx liner (channel passivation) 328, and SiO₂ fill 330 will vary with the depth of the inverted conical frustum pillar. The angle of the sidewall may vary depending on the etchant that is used to form the inverted conical frustrum pillar and the materials in the layers that are being etched. In one non-limiting embodiment, the angle of the sidewall is 77°±3°.

FIG. 3b shows an alternative configuration of a transistor device having a double gate structure 300b. In this example, the elevation cross-section view on the left is depicted as being the same as for structures 300a and 300b; as illustrated in embodiments below, in addition to an inverted conical frustrum shape, the pillar shape may be generally cylindrical with a straight sidewall—similarly, the double gate structure may employ angled walls (as shown in FIG. 3b) or straight walls. As shown in detail 345, a column of double gate structures 300b is formed using a trench 338 and multiple orthogonal trenches 340 and 342. Trenches 338, 340, and 342 may be formed using known fabrication techniques, such as using an etchant.

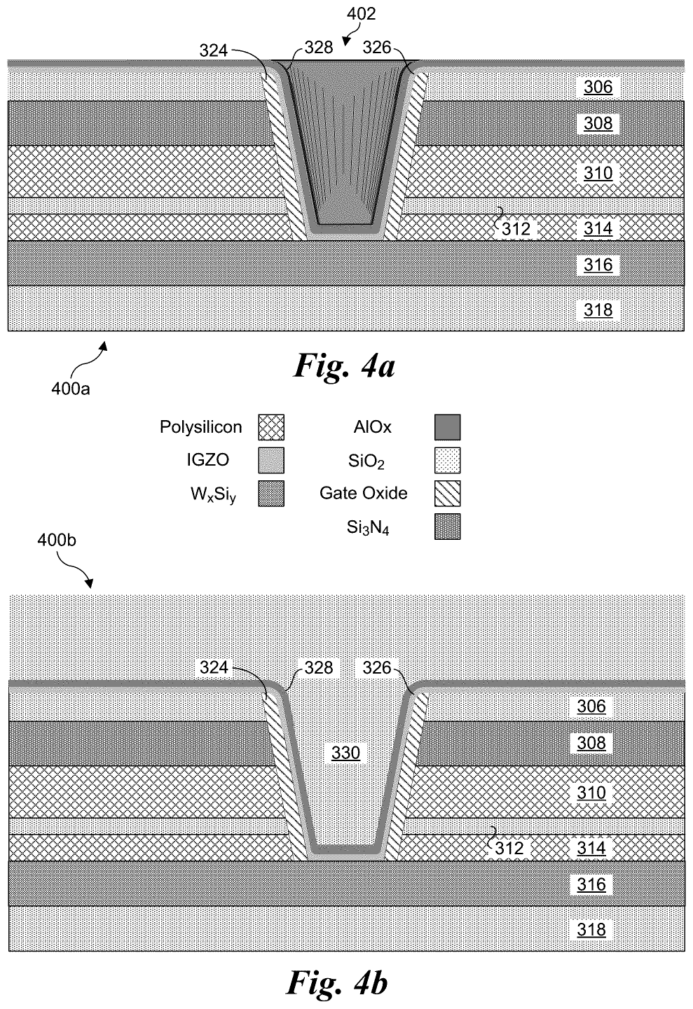

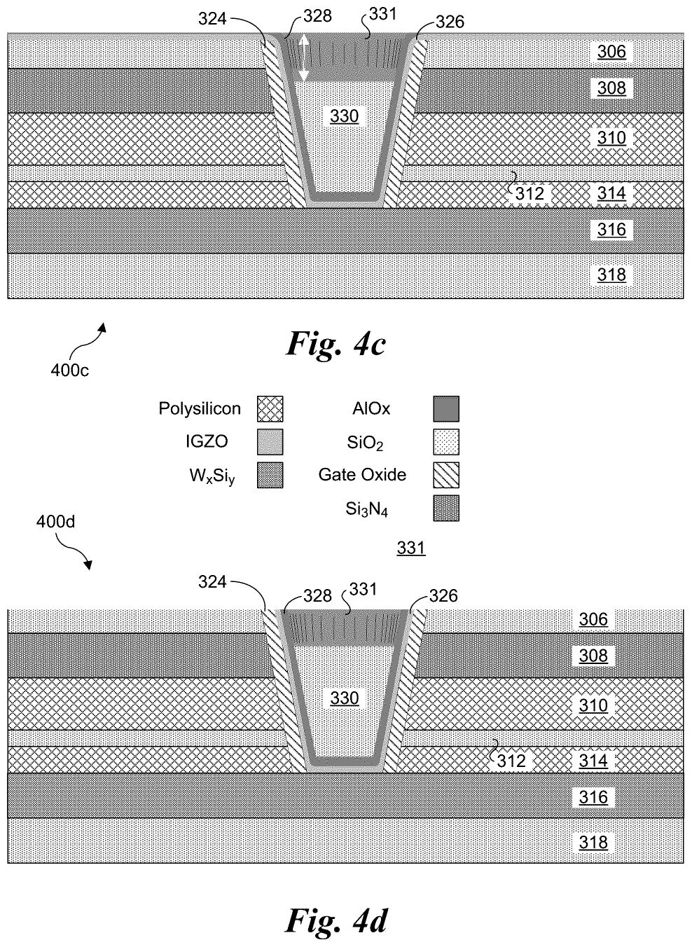

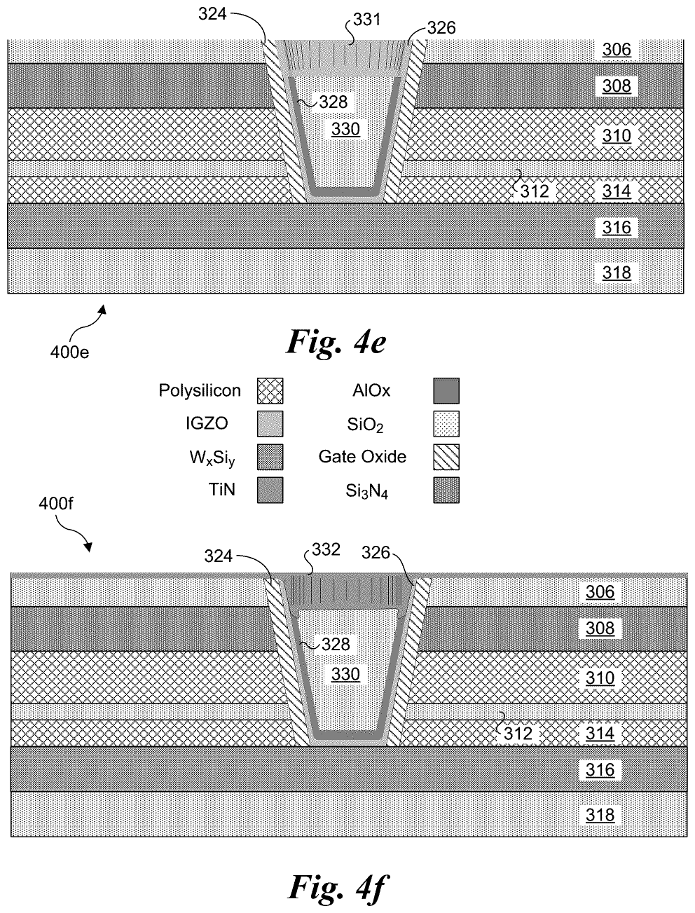

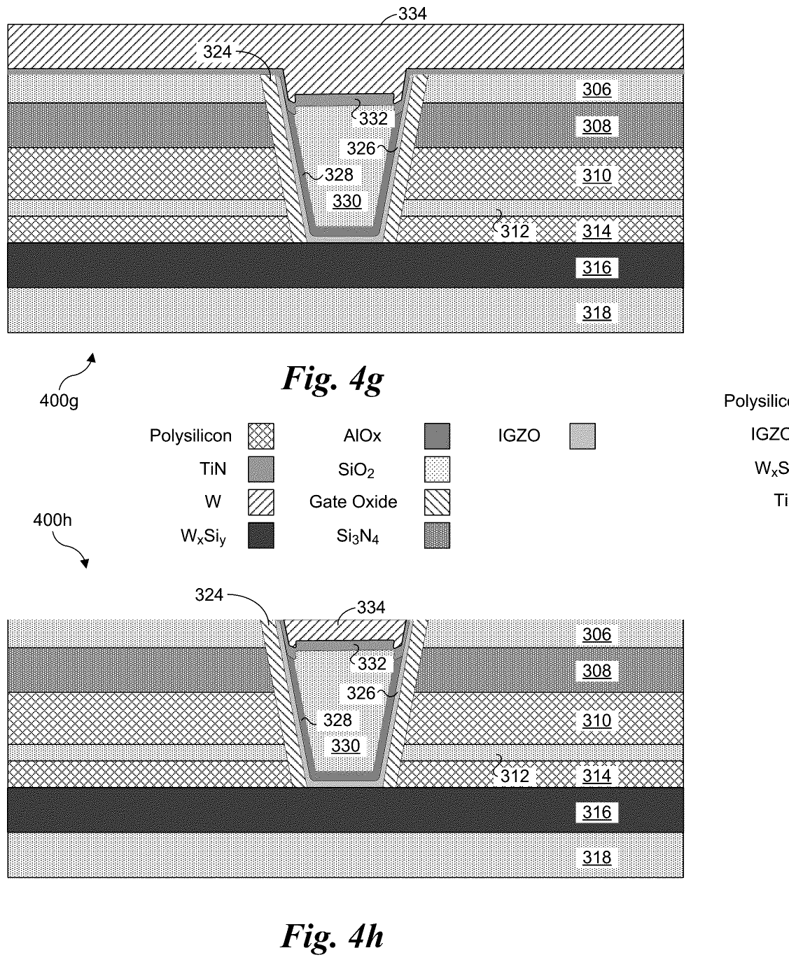

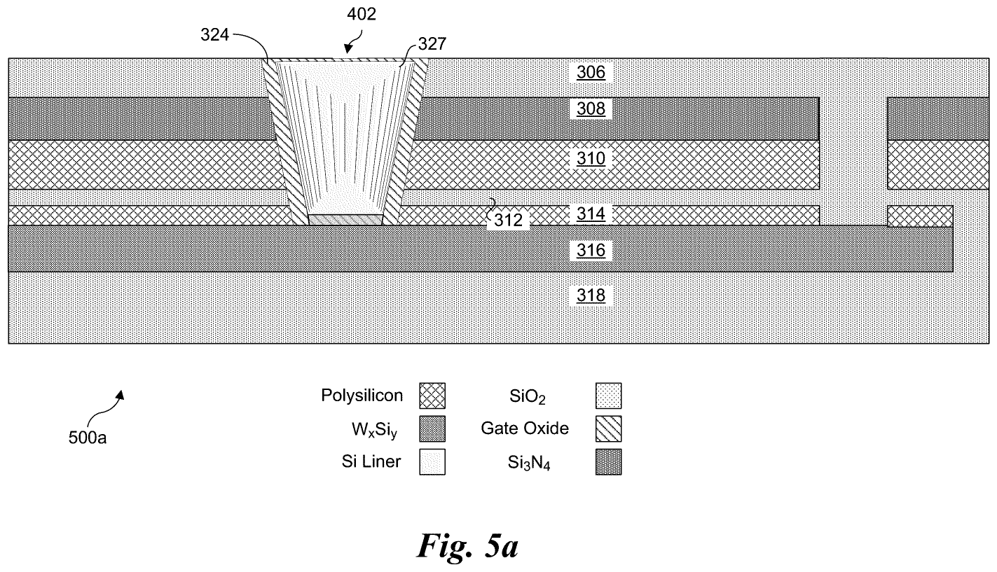

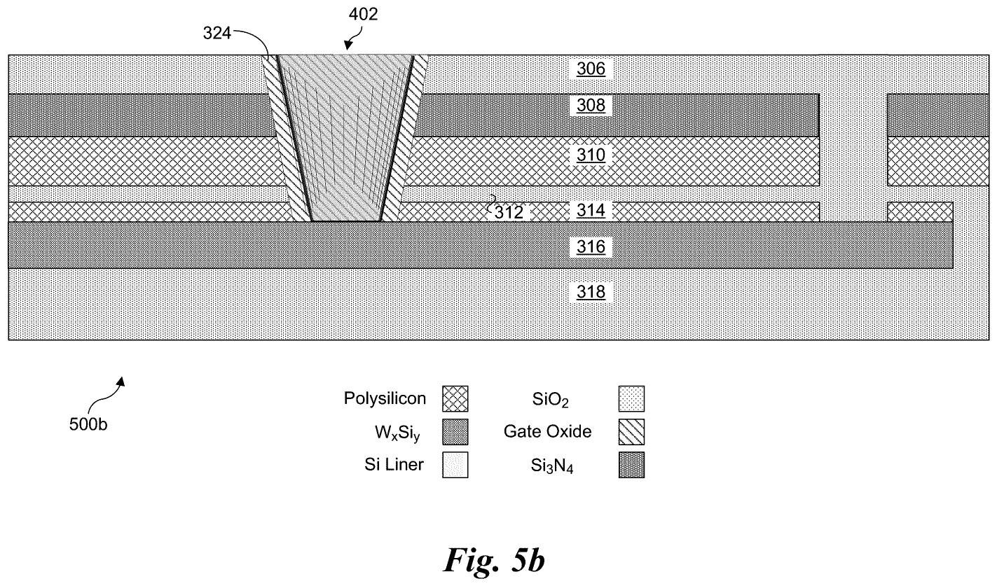

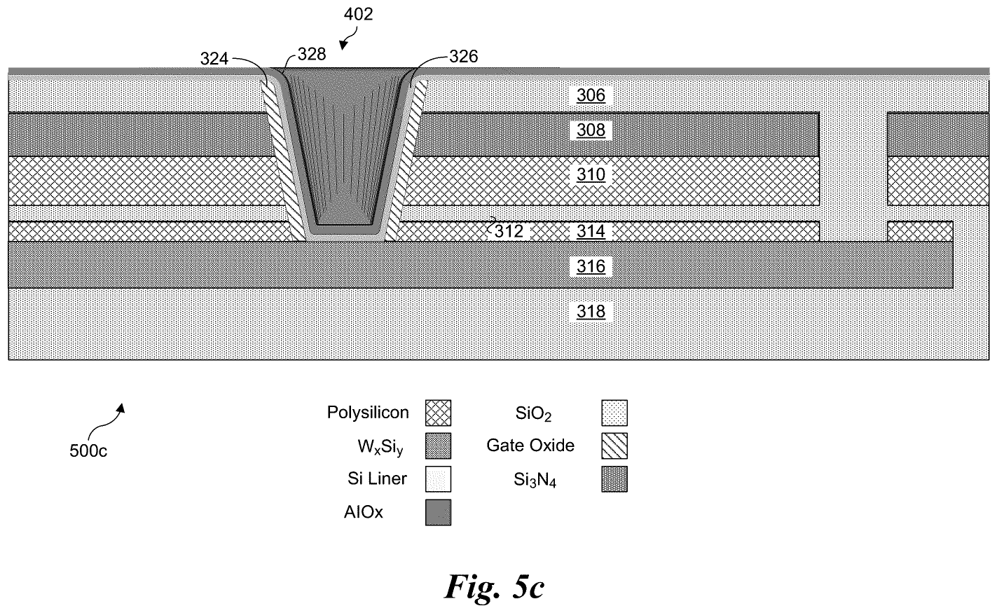

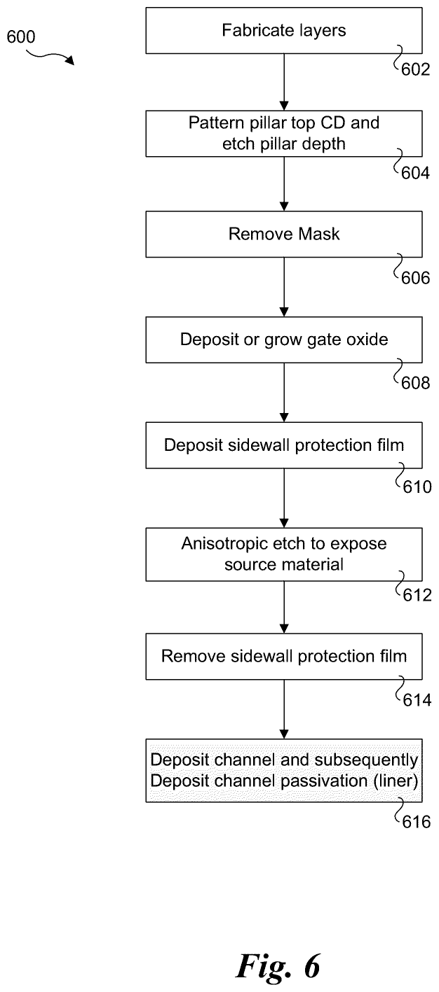

A construction sequence for fabricating transistor structure 300a is illustrated in FIGS. 4a-4h and FIGS. 5a-5c, with operations/steps shown in flowcharts 600, 700, 800, and 900 of respective FIGS. 6, 7, 8, and 9. The sequence begins with an intermediate structure 500a (in FIG. 5a) that is formed using the process of flowchart 600, which begins in a step 602 by fabricating the layers. The fabrication operations may use known techniques for fabricating the layers, such as depositing or otherwise forming the layers shown, beginning with silicon oxide layer 318, followed by WₓSi_{y} layer 316, polysilicon layer 314, silicon oxide layer 312, polysilicon layer 310, silicon nitride layer 308, and silicon oxide layer 306. Next, in a step 604 a pattern of pillars is formed using etching. A pattern of pillars including a pillar 402 is formed in the layered structure using a mask and etching, where the mask pattern has a top critical dimension (CD) for each pillar. In a step 606 the mask is removed. In a step 608 a layer of gate oxide (e.g., SiO₂) 324 is deposited over the sidewall and bottom of pillar 402.

Next, in a step 610, a material such as amorphous silicon is deposited conformally over the gate oxide layer to protect the inner gate oxide sidewall, as depicted by an Si liner 327 in structure 500a of FIG. 5a. In a step 612, an anisotropic etch is performed to expose the source material (WₓSi_{y} layer 316) at the bottom of the pillar. Completion of step 612 yields structure 500a in FIG. 5a. The sidewall protection material (Si liner 327) is removed in a process 614 (yielding structure 500b in FIG. 5b), and a channel and liner (passivation) are deposited in a step 616 (yielding structure 500c in FIG. 5c, which is the same as structure 400a in FIG. 4a). Step 616 includes depositing a layer of IGZO over the gate oxide pillar sidewall and WₓSi_{y} pillar bottom to form the IGZO channel 326, followed by depositing a layer of AlOx over the IGZO to form AlOx liner (channel passivation) 328.

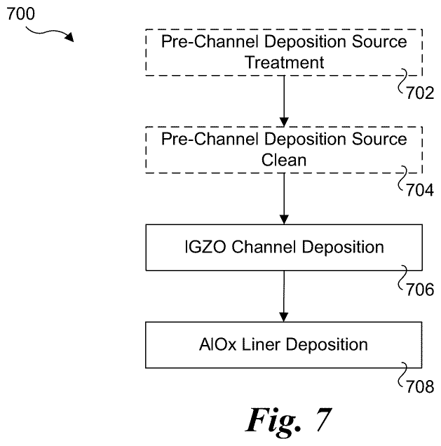

Flowchart 700 of FIG. 7 shows process operations using high-κ (here AlOx, which may also be depicted in the Figures as AlOx) channel passivation deposition to achieve (within back-end-of-line (BEOL) temperature (T) constraints (≤500° C.)) a hermetically sealed IGZO channel of target/goal composition needed for super-high voltage (SHV) operation employing a PVD-based flow (where in a PVD-based flow, the IGZO channel and high-κ channel passivation are deposited by PVD). As used herein, SHV means a breakdown voltage V_{BD} or a drive voltage VDS of at least 30 volts.

In a block 702, an optional pre-channel deposition source treatment is performed. In one embodiment, this process operation is used to convert native oxide (SiOx) of the WₓSi_{y} source (or of a silicon source) to (NH₄)₂SiF₆ (ammonium hexafluorosilicate). In a block 704, an optional pre-channel deposition source cleaning is performed. This is used to sublimate the (NH₄)₂SiF₆ formed in block 702, yielding a bare WₓSi_{y} source (or silicon source) surface. Processes 702 and 704 are not depicted schematically—i.e., the source native oxide and, therefore, its transformation and sublimation are not illustrated. Processes 702 and 704, when used, take place immediately after process 614 in FIG. 6. Given the former and latter statements, completion of processes 702 and 704 (which, if used, take place after process 614) does not modify structure 500b in FIG. 5b.

In a block 706, IGZO channel deposition is performed to deposit the IGZO. In one embodiment, IGZO PVD is performed at room temperature (RT)—450° C., with a process pressure of 100-10,000 mTorr, power of 1-30 kW, and 1-300 SCCM (standard cubic centimeters per minute) total Ar (Argon) flow. In one embodiment, deposited IGZO comprises In:Ga:Zn with a 1:1:1 composition. The IGZO target is sputtered by Ar to have a deposited film thickness goal of 4-20 nm, in one embodiment.

In a block 708, AlOx liner deposition is performed employing AlOx channel passivation deposition. In one embodiment, AlOx PVD is performed at RT-350° C., with a 100-10,000 mTorr process pressure, power of 1-10 kW, 1-300 SCCM total Ar flow and 1-100 SCCM of O₂ flow. A pure Al target is sputtered by Ar and O₂. The deposited film thickness goal is 2-30 nm, in one embodiment. The deposited film composition (Al:O) goal is a ratio of 2:3, in one embodiment. In one embodiment, the AlOx etch rate (in a dilute hydrofluoric (HF) acid solution) is 6.5-12.0 Å/s.

Structure 500c of FIG. 5c (which is equivalent to structure 400a of FIG. 4a) shows the state of the semiconductor structure following the operations of blocks 706 and 708. As shown, this includes deposition of IGZO to form amorphous IGZO channel 326 over which AlOx liner 328 is deposited. As further shown, the IGZO channel material is deposited over SiO₂ layer 306, gate oxide pillar sidewall 324, and WₓSi_{y} (part of source) pillar bottom 316. During these same processing operations/steps, the IGZO channel and AlOx liner (channel passivation) materials would be deposited over the sidewalls and bottoms of other pillars (not separately shown).

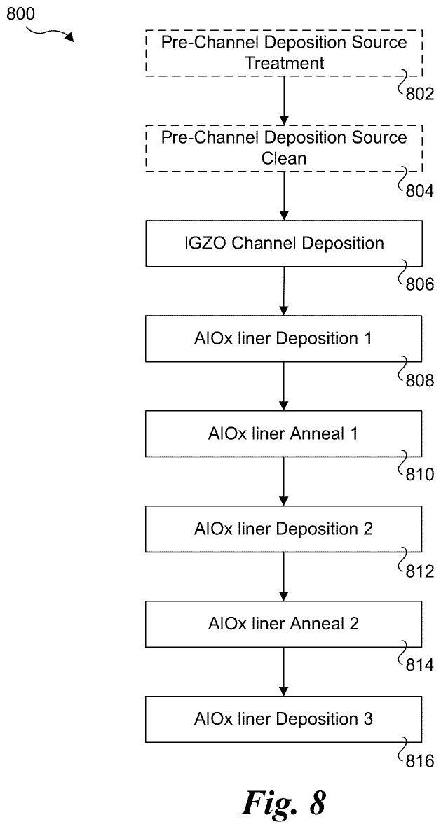

Flowchart 800 of FIG. 8 shows process operations using a novel combination of IGZO ALD followed by a high-κ (here AlOx) channel passivation deposition strategy to achieve (within BEOL T constraints) a hermetically sealed IGZO channel of target/goal composition (including [Vₒ] and [H]) needed for SHV operation and employing an ALD-based flow (IGZO channel and AlOx channel passivation deposited by ALD). As with the PVD-based flow in FIG. 7, pre-channel deposition source treatment and pre-channel deposition source cleaning operations may be (optionally) performed in blocks 802 and 804, respectively. In one embodiment, pre-channel deposition source treatment employs 15-120 seconds of (Ar/N₂/H₂ plasma+NF₃)-based dry treatment at 30° C. & 1-10 TOM A remote plasma source with power=4-6 kW and RF frequency=1.8-2.2 MHz is used, in one embodiment. In one embodiment, pre-channel deposition source cleaning employs 150-450 seconds of heating at 300-500° C. under vacuum (base pressure). Processes 802 and 804 are not depicted schematically—i.e., the source native oxide and, therefore, its transformation and sublimation are not illustrated. Processes 802 and 804, when used, take place immediately after process 614 in FIG. 6. Given the former and latter statements, completion of processes 802 and 804 (which, if used, take place after process 614) does not modify structure 500b in FIG. 5b.

In a block 806, IGZO channel deposition is performed. In one embodiment, IGZO ALD is performed at 125-500° C. In one embodiment, a combination of homoleptic Ga and Zn precursors with alkyl ligands is used with an In precursor with alkyl and alkylamino (nitrogen-containing) ligands and with a strong oxidant, such as O₃. The goal IGZO thickness is 4-20 nm in one embodiment. The goal IGZO composition (In:Ga:Zn) is 1:1:1 or 1:2:1 in some embodiments. An IGZO ALD supercycle is comprised of component InOx ALD, GaOₓ ALD, and ZnOx ALD cycles. IGZO channels of different composition may be obtained by adjusting, within an IGZO ALD supercycle, the ratios among numbers of component InOx ALD (e.g., In precursor/O₃ ALD), GaOₓ ALD (e.g., Ga precursor/O₃ ALD), and ZnOx ALD (e.g., Zn precursor/O₃ ALD) cycles, respectively.

The high-κ (here AlOx) channel passivation deposition strategy follows the above IGZO ALD process and employs a method in which 1) low-temp (LT) high-κ (here AlOx) channel passivation ALD/post-deposition anneal (PDA) cycling is performed followed by final high-temp high-κ (here AlOx) channel passivation ALD; and 2) a strong oxidant (here, ozone (O₃)) is used for the low-temp and high-temp (HT) high-κ (here AlOx) channel passivation ALD processes as well as the PDA. In a block 808, a first AlOx liner (channel passivation) deposition process is performed. This comprises a Low-Temp (LT) AlOx channel passivation deposition by ALD and the employs the following. A strong oxidant (e.g., O₃) is used for the ALD co-reactant: Drive extent of reaction with Al precursor (e.g., minimize residual H content in AlOx). LT is used for AlOx deposition: Reduce 0 gettering from IGZO by Al precursor (e.g., TMA (trimethylaluminum, Al(CH₃)₃)) for AlOx thickness below hermeticity limit @ T; Ultrathin (e.g., 1 nm) AlOx deposition: Remain below AlOx hermeticity limit at T to allow for post-deposition correction. In one embodiment, AlOx ALD is performed at 225° C. with trimethylaluminum (TMA) precursor and O₃ co-reactant. In one embodiment, the goal AlOx thickness is 1 nm. In one embodiment, the goal AlOx composition (Al:O) is 2:3.

Next, in a block 810, a first AlOx anneal process is performed. This comprises a first High-Temp (HT) IGZO Channel/AlOₓ channel passivation treatment. An anneal in strong oxidant (e.g., O₃) is performed to correct for 1) O depletion from and H addition to IGZO by the operation in block 808; and 2) sub-optimal AlOx liner composition due to low T of the operation in block 808 (e.g., minimize potential for H to be transferred to IGZO with thermal stresses downstream of in-scope portion of flow). In one embodiment, the process in block 810 employs 15-60 minutes of heating at 300-400° C. in 1-10 T O₃.

In a block 812, a second AlOx liner deposition process is performed. This comprises an LT AlOx channel passivation deposition by ALD. In one embodiment, the process employs O₃ for the ALD co-reactant: Drive extent of reaction with Al precursor (e.g., minimize residual H content in AlOx). LT is used for AlOx deposition: Reduce O gettering from IGZO by Al precursor (e.g., TMA (Al(CH₃)₃)) for AlOx thickness below/at hermeticity limit @ T; Ultrathin (e.g., 1 nm) AlOx deposition: Complete LT AlOx deposition to achieve AlOx thickness (thickness sum for AlOx liners deposited via blocks 808 and 812, respectively)—at hermeticity limit at T. In one embodiment, AlOx ALD is performed at 225° C. with trimethylaluminum (TMA) precursor and O₃ co-reactant. Goal AlOx thickness is 1 nm, in one embodiment. In one embodiment, the goal AlOx composition (Al:O) is 2:3.

In a block 814, a second AlOx anneal process is performed. This comprises a second IGZO Channel/AlOₓ channel passivation treatment. An anneal in strong oxidant (e.g., O₃) is performed to correct for 1) O depletion from and H addition to IGZO by the operation in block 812; and 2) sub-optimal AlOx liner composition due to low T of the operation in block 812 (e.g., minimize potential for H to be transferred to IGZO with thermal stresses downstream of in-scope portion of flow). In one embodiment, the 814 process employs 15-60 minutes of heating at 300-400° C. in 1-10 T O₃.

In a block 816, a third AlOx liner deposition process is performed. This comprises an HT AlOx channel passivation deposition. In one embodiment, the process employs O₃ for the ALD co-reactant: Drive extent of reaction with Al precursor (e.g., minimize residual H content in AlOₓ). HT is used for the remainder of the AlOx deposition: HT (vs. LT) deposition provides improved AlOx film quality (e.g., composition) without risk to underlying IGZO. A sufficient thickness (e.g., 3 nm) of HT deposition is used to achieve total AlOx thickness (thickness sum for AlOx liners deposited via blocks 808, 812, and 816, respectively) that ensures post-processing continuity (e.g., total AlOx thickness of 5 nm). In one embodiment, HT AlOx ALD is performed at 300-400° C. with TMA precursor and O₃ co-reactant. In one embodiment, the goal AlOx thickness by HT AlOx ALD=0-28 nm. In one embodiment, the goal AlOx composition (Al:O) is 2:3.

Structure 500c of FIG. 5c (which is equivalent to structure 400a of FIG. 4a) shows the state of the semiconductor structure following the operations of blocks 806 through 816, inclusive.

An ALD-based flow (IGZO channel and high-κ (here AlOx) channel passivation deposited by ALD, as illustrated in FIG. 8) allows for use in a range of architectures (including all of those presented here) due to the high conformality of the associated ALD films and afforded by the combined chemoselective toggles in an ALD-based flow.

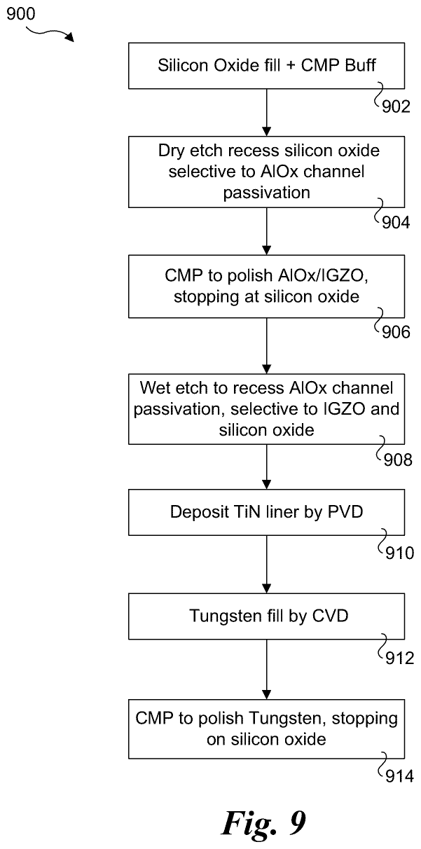

Note that completion of the in-scope portion of the PVD-based flow (steps shown in FIG. 7) or completion of the in-scope portion of the ALD-based flow (steps shown in FIG. 8) entails transformation from structure 500b in FIG. 5b to structure 500 c in FIG. 5c. Also note that structure 500 c in FIG. 5c is equivalent to structure 400a in FIG. 4a. Moving to flowchart 900 of FIG. 9, the following steps/operations are performed with reference to the structures 400a-400h in FIGS. 4a-4h, respectively. In a step 902, an oxide fill operation followed by a subsequent buff using chemical-mechanical planarization (CMP) is performed on structure 400a of FIG. 4a to yield structure 400b of FIG. 4b. During this step, a fill of silicon oxide 330 is added. Next, in a step 904 a dry etch recess of the silicon oxide 330 is performed. As shown in FIG. 4c, a structure 400c is obtained by etching the silicon oxide 330 (selective to the AlOx channel passivation) 328) shown in structure 400b of FIG. 4b to yield the recess 331 shown in structure 400c of FIG. 4c. In one embodiment, recess 331 has a depth of approximately 1100 Å. In a step 906, CMP is used to polish the AlOx 328 and IGZO 326 deposited over the top of silicon oxide layer 306, as shown in structure 400c of FIG. 4c, and stop on the top of the silicon oxide layer 306, yielding structure 400d of FIG. 4d.

Next, in a step 908, a wet etch is performed on structure 400d in FIG. 4d to recess AlOx channel passivation 328 selective to IGZO 326 and silicon oxide using NH₄OH (ammonium hydroxide solution, also called ammonia solution, ammonia aqueous or ammonia water), leaving an annular hoop of IGZO 326, as shown in structure 400e of FIG. 4e. In a step 910, a TiN 332 liner is deposited using PVD on structure 400e of FIG. 4e to obtain the structure 400f shown in FIG. 4f.

Continuing at a step 912, a tungsten fill 334 is performed using CVD on structure 400f in FIG. 4f to obtain a structure 400g shown in FIG. 4g. The process flow illustrated in FIG. 9 is completed in a step 914 during which a portion of the tungsten fill 334 (in structure 400g of FIG. 4g) is removed using CMP, stopping at silicon oxide layer 306, to obtain a structure 400h shown in FIG. 4h. Subsequent operations not separately shown are then performed to obtain the transistor structure 300a shown in FIG. 3a using known conventional techniques.

In one embodiment, the silicon oxide layers are deposited as silicon oxide films using Tetraethyl orthosilicate (TEOS), which has a chemical formula SiC₈H₂₀O₄. In one embodiment, the silicon nitride layers 304 and 308 are deposited using low-pressure chemical vapor deposition (LPCVD).

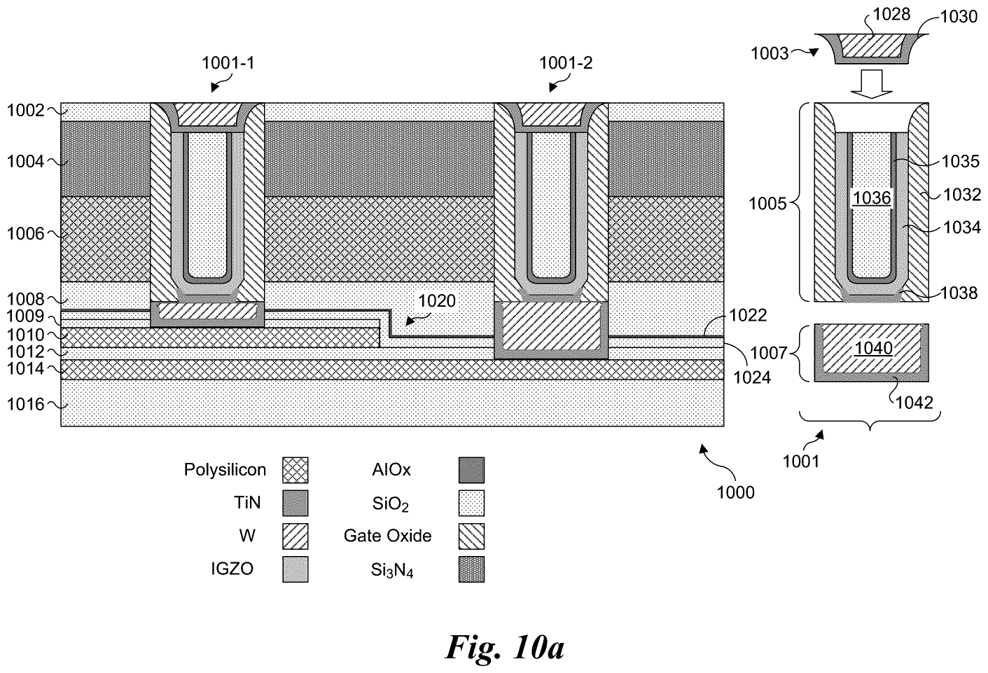

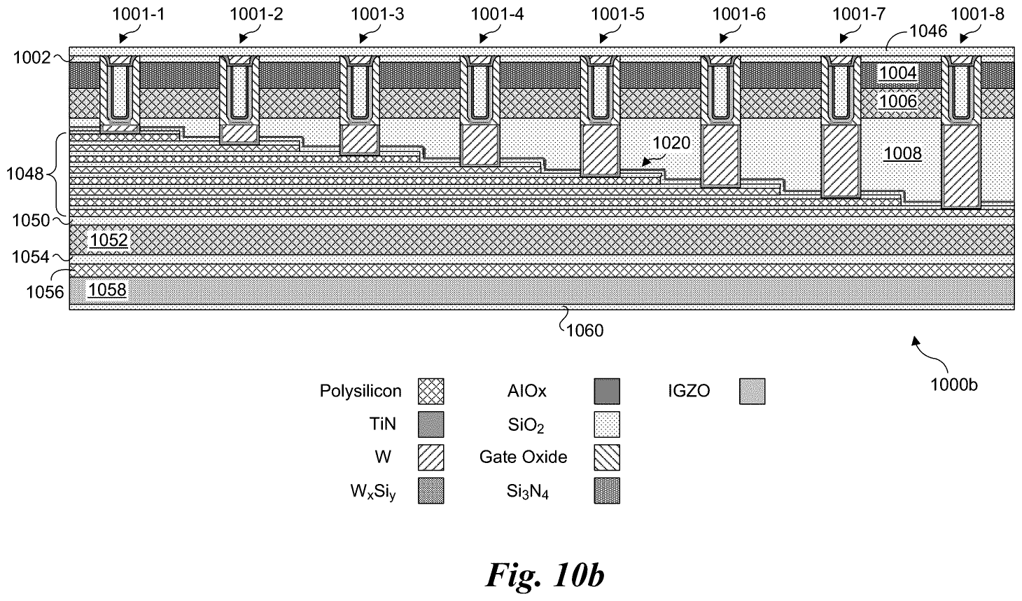

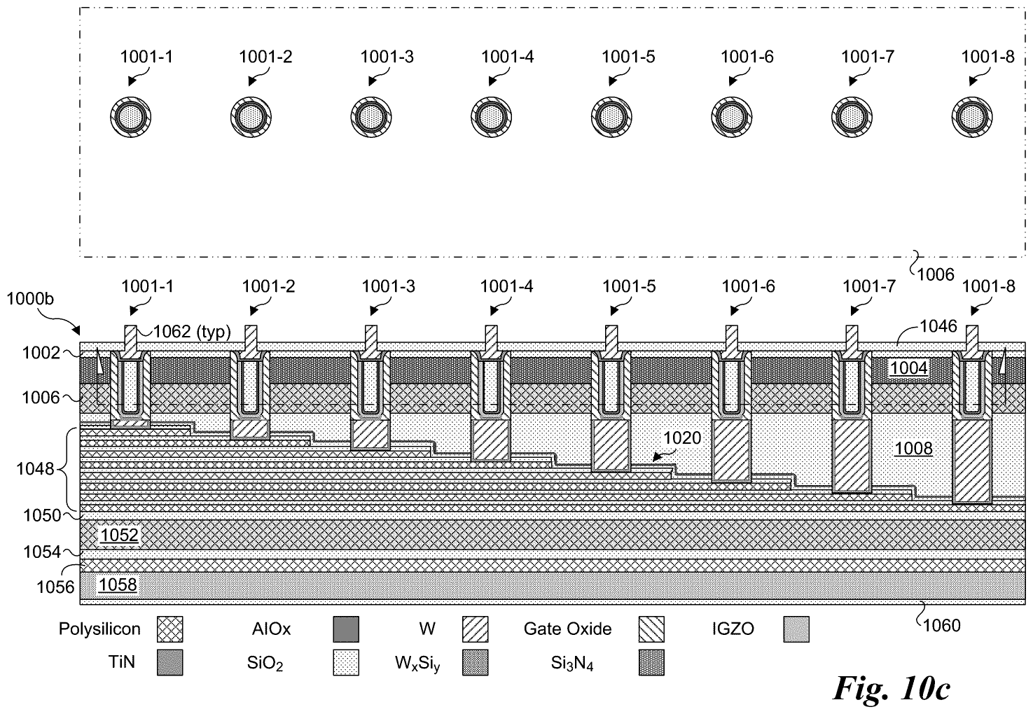

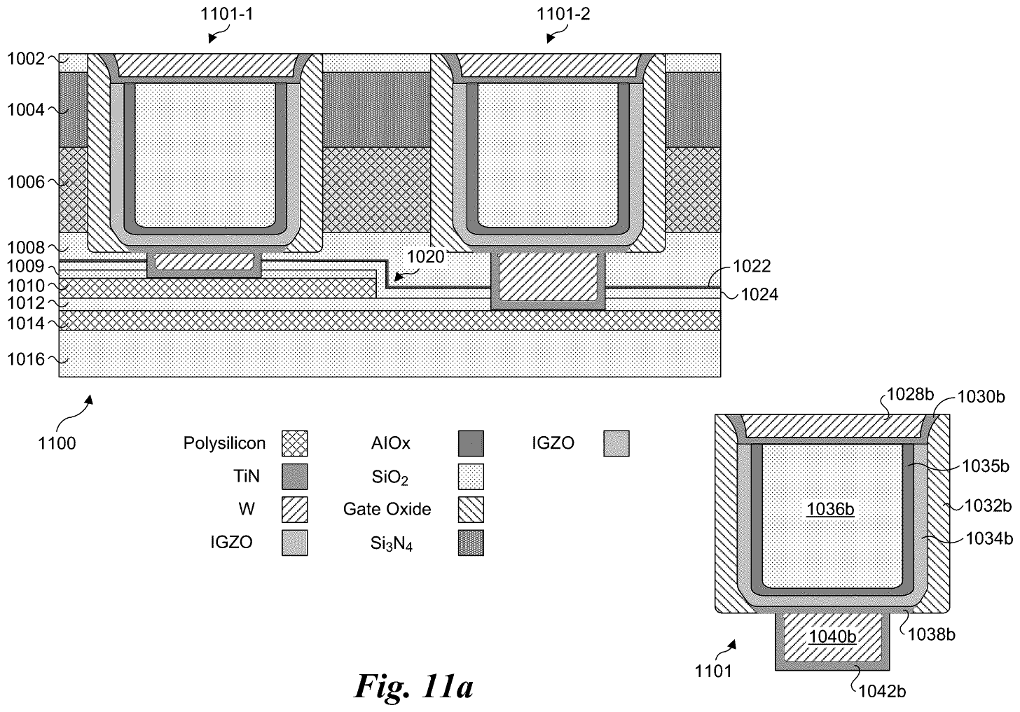

FIG. 10a shows a portion of a semiconductor structure 1000 in which two GAA TFT devices 1001-1 and 1001-2 having a first alternative configuration are shown. The layer structure of the semiconductor substrate includes a silicon oxide layer 1002, a silicon nitride layer 1004, a polysilicon layer 1006, a silicon oxide layer 1008, a silicon oxide layer 1009, first and second wordlines 1010 and 1014, and silicon oxide layers 1012 and 1016. First wordline 1010 includes a “staircase” structure 1020 comprising a pattern of silicon nitride 1022 formed over a pattern of silicon oxide 1024. Generally, the silicon oxide for layers 1009, 1012, and 1016 will have the same composition, while the silicon oxide 1024 may have the same or a different composition than layers 1009, 1012, and 1016.

As shown in the upper right-hand portion of FIG. 10a, a GAA TFT device 1001 includes an upper W/TiN contact 1003 comprising W 1028 and TiN 1030 formed above a pillar 1005 having a straight sidewall including a gate oxide outer wall 1032, an IGZO channel 1034, an AlOx liner (channel passivation) inner wall 1035, and a silicon oxide core 1036. A W/TiN wordline contact 1007 comprising W 1040 and TiN 1042 is formed below pillar 1005. A TiN structure 1038 comprising an optional bottom contact conductive liner may be disposed between a base portion of IGZO channel 1034 and W/TiN wordline contact 1007 in some embodiments.

FIG. 10b shows a cutaway view of a portion of a semiconductor device 1000b that includes GAA TFT devices 1001-1, 1001-2, . . . 1001-8. Semiconductor device 1000b generally comprises the layer structure shown for semiconductor structure 1000 in FIG. 10a above with additional layers and structures including an SiO₂ layer 1046 and structure 1048, which comprises polysilicon wordlines with a layer of silicon oxide disposed between adjacent polysilicon wordlines. The additional layers below structure 1048 include silicon oxide layers 1050, 1054, and 1060, polysilicon layers 1052 and 1056, and WₓSi_{y} layer 1058. FIG. 10b also shows further details of the staircase structure 1020, which includes a step-down for each respective GAA TFT device 1001-1, 1001-2, . . . 1001-8. Also, the lower W/TiN contact portion of the respective GAA TFT devices 1001-1, 1001-2, . . . 1001-8 is increasingly taller to provide a connection between a given GAA TFT device 1001 and a respective wordline within structure 1048.

FIG. 10c adds a plan view (upper portion of figure) to what is shown in FIG. 10b and reflects additional patterning between FIGS. 10b and 10c (e.g., tungsten plug 1062 formation). Persons of skill in the art will recognize that an actual semiconductor device, such as but not limited to a 3D NAND device, would have sets of GAA TFT devices 1001 coupled to respective wordlines in structure 1048 disposed in multiple layers. For example, see FIG. 15 below. This includes material 1062 (e.g., Tungsten in the illustrated embodiment) that would be coupled to signal routing formed in a layer or layers above the layered structure shown in FIGS. 10b and 10c.

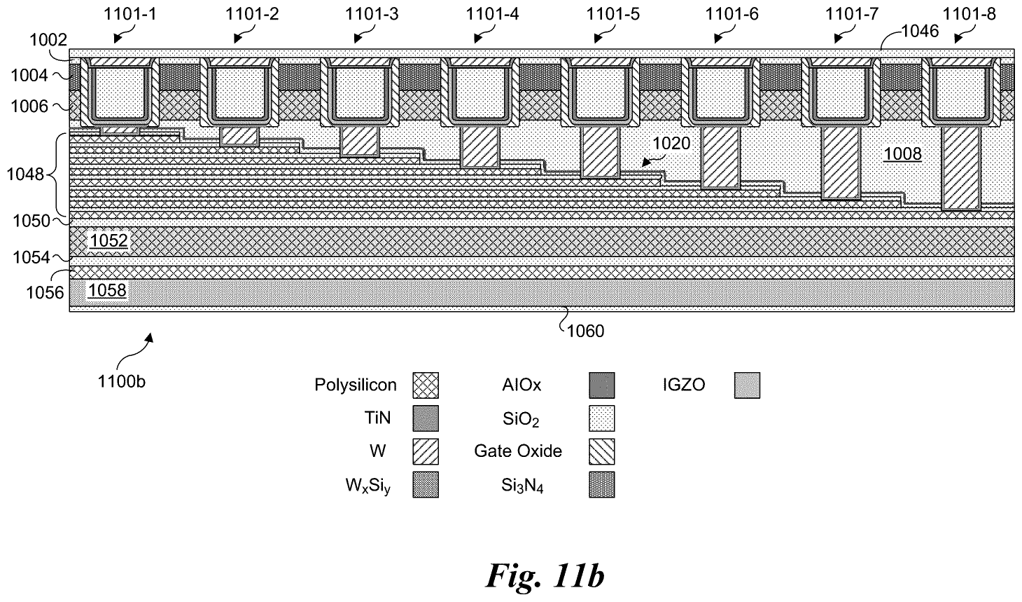

FIGS. 11a and 11b respectively show a semiconductor structure 1100 and a cutaway view of a portion of a semiconductor device 1100b that includes GAA TFT devices 1101 that are a first variant of GAA TFT devices 1001. As shown by like-numbered layers and components, structures of semiconductors structures 1000 and 1100 are generally similar, with the difference being the diameter of the GAA TFT devices 1001 and 1101. As shown in the detailed view at lower right portion of FIG. 11a, GAA TFT devices 1101 include an upper W/TiN contact comprising W 1028b and TiN 1030b formed above a pillar having a straight sidewall including a gate oxide outer wall 1032b, an IGZO channel 1034b, an AlOx channel passivation inner wall 1035b, and a silicon oxide core 1036b. As with GAA TFT devices 1001, an optional TiN structure 1038b is disposed between a base of IGZO channel 1034b and a lower W/TiN contact comprising W 1040b and TiN 1042b.

Generally, the layers and structures in semiconductor devices 1000b and 1100b are similar, as indicated by like reference numbers. The notable different is GAA TFT devices 1101 (1101-1, 1101-2, . . . 1101-8) have replaced GAA TFT devices 1001 (1001-1, 1001-2, . . . 1001-8) in semiconductor device 1100b.

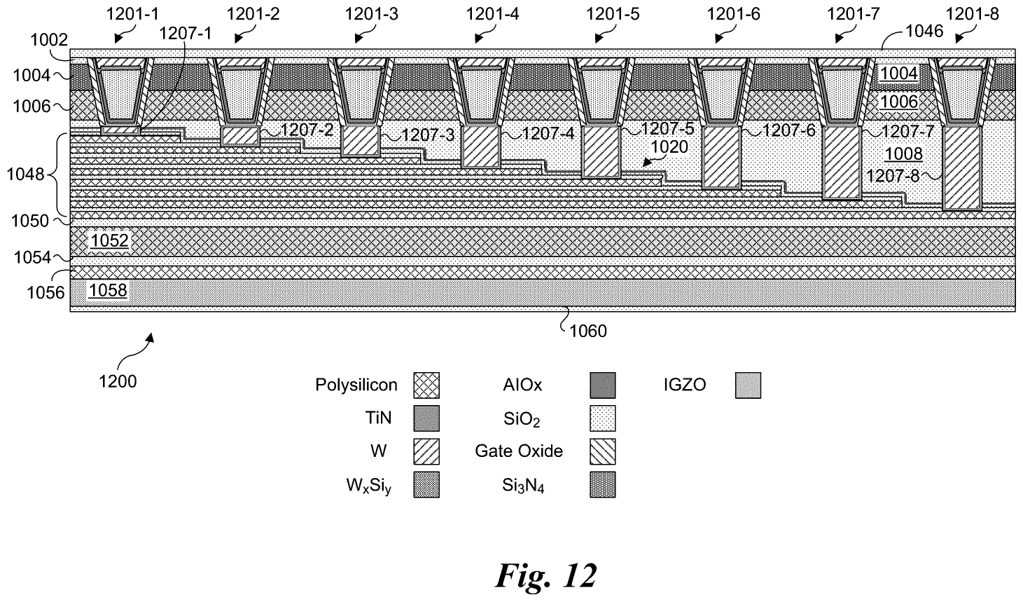

FIG. 12 is a diagram illustrating a cross-section view of a semiconductor device 1200 showing vertical wordline drivers (GAA TFT devices 1201 (1201-1, 1201-2, . . . 1201-8)) having the GAA TFT structure of FIG. 3a and connecting to respective wordlines, according to one embodiment. Each of GAA TFT devices 1201-1, 1201-2, . . . 1201-8) is connected to a respective W/TiN wordline contact 1207-1, 1207-2, . . . 1207-8. In this example, the diameter of the GAA TFT devices 1201 at the bottom of the pillar, referred to as VWD (Vertical Wordline Driver) CD (critical dimension) is approximately equal to the CD of the wordline contact (WC).

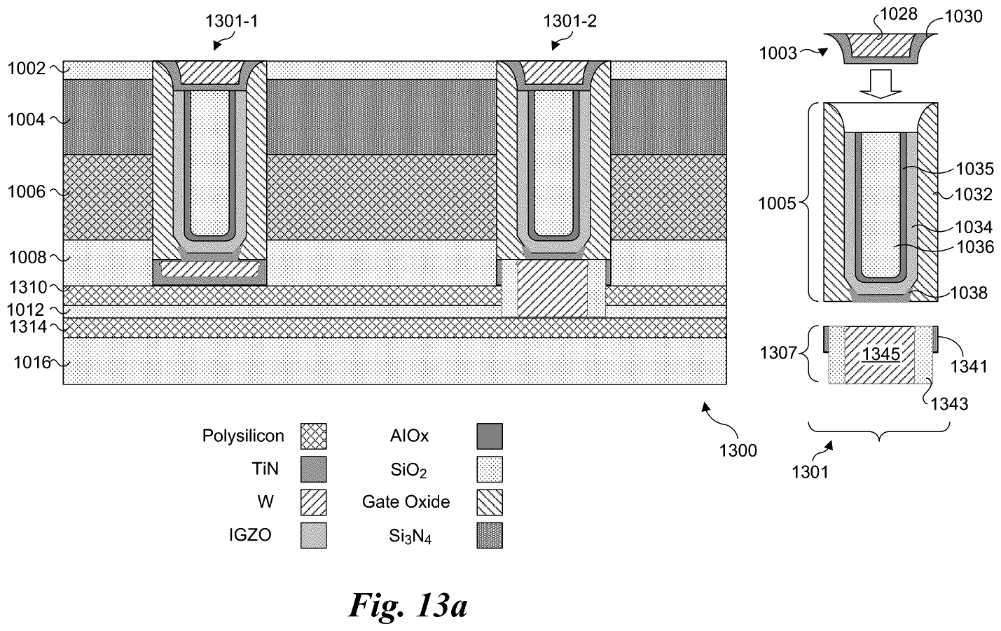

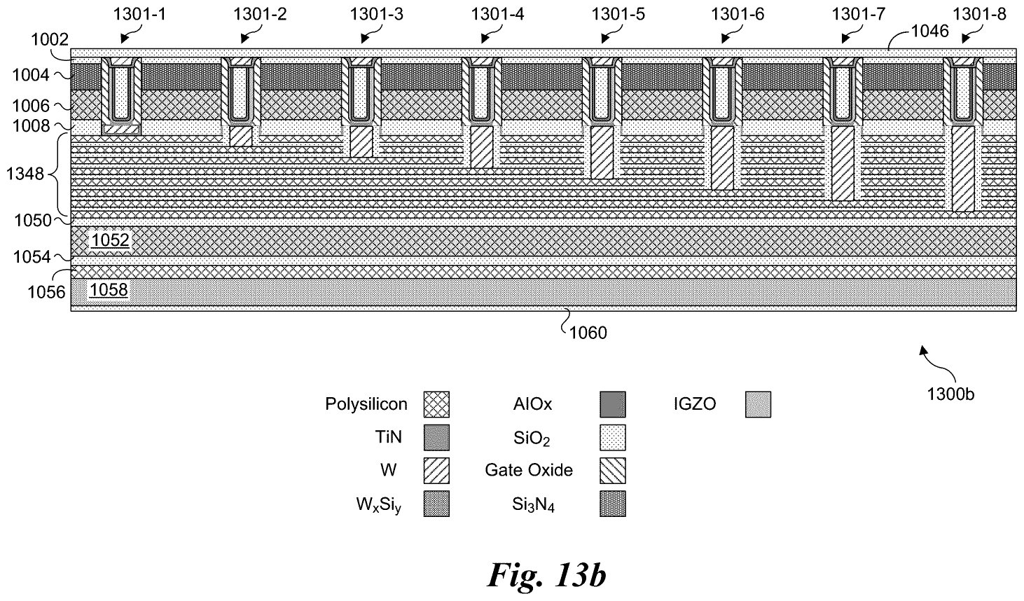

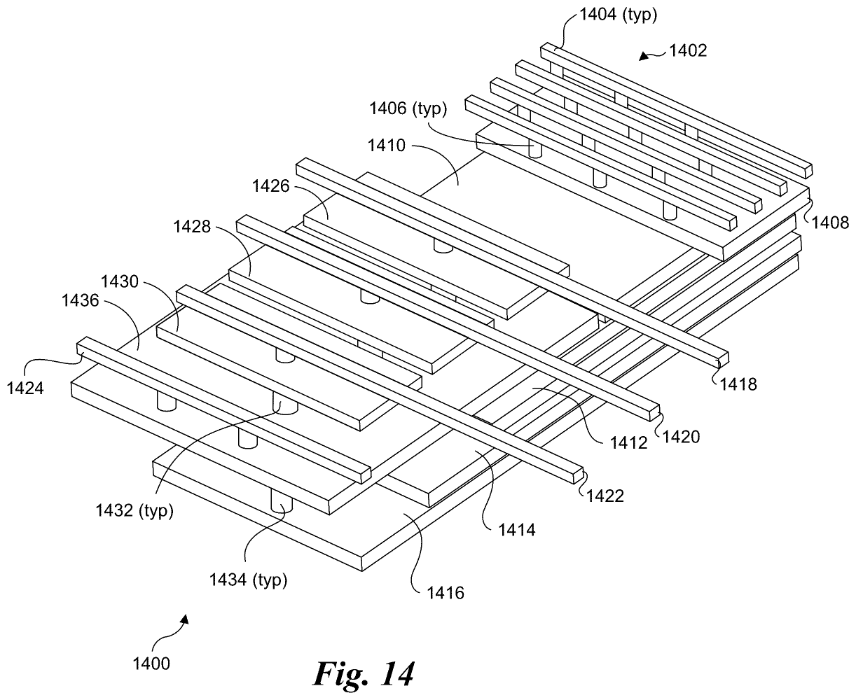

FIGS. 13a and 13b respectively show a semiconductor structure 1300 and a cutaway view of a portion of a semiconductor device 1300b that includes GAA TFT devices 1301 that are a second variant of GAA TFT devices 1001. Generally, as shown by layers and structures with the same reference numbers in semiconductor structures 1000 and 1300, most of the structures are similar. However, under semiconductor structure 1300, the wordline contacts 1307 of GAA TFT devices 1301 (1301-1, 1301-2, . . . 1301-8) are extended to contact a respective wordline, as depicted by wordlines 1310 and 1314 in FIG. 13a. As shown in the detail view of GAA TFT device 1301, the structure for upper W/TiN contact 1003 and pillar 1005 are the same as for semiconductor structure 1000 shown in FIGS. 10a and 10b above. The difference is the structure of the wordline contact 1307, which comprises a TiN shoulder 1341, coupled to a pillar comprising an SiO₂ insulating liner 1343 and having a tungsten fill 1345. As shown in FIG. 13b, 1348 illustrates polysilicon wordlines separated by SiO₂ layers. The wordline contacts 1307 for GAA TFT devices 1301-1, 1301-2, . . . 1301-8 have different vertical lengths that extend to a respective wordline within 1348. Note that FIGS. 13a and 13b do not indicate a staircase architectural feature. Various figures herein show TiN drawn on the bottom-side contact. However, this is merely illustrative and non-limiting, as the use of TiN on the bottom-side contact is optional as some embodiments (not separately shown) do not employ such metal liner film.

Various figures herein show TiN drawn on the bottom-side contact. However, this is merely illustrative and non-limiting, as the use of TiN on the bottom-side contact is optional as some embodiments (not separately shown) do not employ such metal liner film.

Generally, the combinations of vertical transistor structures (e.g., GAA TFT devices) and wordline contacts shown in the figures above are exemplary and non-limiting. Those skilled in the art will appreciate other combinations not separately shown may be implemented. For example, the vertical transistor structures (GAA TFT devices 1201) in FIG. 12 could be combined with the wordline contact of other figures, wherein under the combination VWD CD≥WC CD.

FIG. 14 shows a 3D view of an abstracted memory device 1400. The memory device includes a 3D array 1402 that has a structure similar to 3D array 222 shown in FIG. 2 and discussed above. For simplicity, the components for 3D array 1402 are depicted as bitlines 1404 coupled to pillars 1406, an SGD layer 1408, and wordlines 1410, 1412, 1414, and 1416. Memory device 1400 further includes drain-routing lines 1418, 1420, and 1422, a vertical wordline driver gate 1436, a vertical wordline driver gate-routing line 1424, drain pads 1426, 1428, and 1430, vertical wordline drivers 1432, and wordline contacts 1434. As will be recognized by those skilled in the art, an actual memory device would have similar components and structures repeated many times. Moreover, the internal structures of a memory device based on the teaching and principles disclosed herein may have a configuration similar to any of the embodiments described and illustrated herein, as well as variants employing combinations of features of the illustrated embodiments.

Aspects of the figures and diagrams shown herein are simplified for illustrative purposes and ease of explanation. The transistor structures are also not drawn to scale and are representative of a higher number of similar transistor structures in actual devices. As will be recognized by those skilled in the art, such devices will generally employ high wordline counts (e.g., in the hundreds) and large arrays of memory cells in a 3D structure.

In the foregoing embodiments, the liner materials are illustrative of some exemplary and non-limiting materials that may be used as a liner. More generally, the liners comprise a film with the following considerations: a high-κ material, low hydrogen content, need to avoid absorption of H₂O during processing, thickness in line with stable device Vₜ due to fixed charges in the film, and hermetic sealing capability to prevent any interaction between IGZO and downstream steps.

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein, a list of items joined by the term “at least one of” can mean any combination of the listed terms. For example, the phrase “at least one of A, B or C” can mean A; B; C; A and B; A and C; B and C; or A, B and C.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1. A method for forming a hermetically sealed Indium Gallium Zinc Oxide (IGZO) channel contained within a vertical wordline driver supporting a drive voltage of at least 10 volts comprising:
forming a pillar having a sidewall in a stacked layer semiconductor structure including a source layer, wherein forming the pillar exposes layers in the semiconductor structure and exposes a portion of the source layer at a bottom of the pillar;
forming a gate oxide film over exposed layers in the semiconductor structure including the sidewall of the pillar and over the exposed portion of the source layer;
depositing a sacrificial silicon liner over the gate oxide;
selectively removing the sacrificial silicon liner and the gate oxide at the bottom of the pillar to punch through to the source layer; removing the sacrificial silicon liner from the gate oxide pillar sidewall;
forming a film of IGZO over the gate oxide pillar sidewall and a portion of the source layer where the gate oxide was punched through; and
using a high-κ channel passivation deposition process to form a film of a high-κ material over the film of IGZO to form a hermetically sealed IGZO channel.

2. The method of claim 1, wherein the high-κ material comprises aluminum oxide (AlOx).

3. The method of claim 1, wherein the pillar has an inverted conical frustum shape with VWD CD≥WC CD or has straight sidewalls with VWD CD>WC CD or VWD CD=WC CD, where VWD is vertical wordline driver, WC is wordline contact, and CD is critical dimension.

4. The method of claim 1, wherein the high-κ material is deposited using a physical vapor deposition (PVD) process.

5. The method of claim 4, comprising:
using PVD to perform an IGZO deposition process to form an IGZO film over the gate oxide film and exposed source; and
using PVD to perform an aluminum oxide (AlOx) deposition process to deposit an AlOx liner (channel passivation) over the IGZO film.

6. The method of claim 5, wherein the AlOx deposition process comprises sputtering an Al target in a chamber with Argon (Ar) and Oxygen at a wafer temperature of ≤500° C.

7. The method of claim 1, wherein the high-κ material is deposited using an atomic layer deposition (ALD) process.

8. The method of claim 7, comprising:
using ALD to perform an IGZO deposition process utilizing a combination of homoleptic Ga and Zn precursors with alkyl ligands, a heteroleptic Indium (In) precursor, and a strong oxidant to form an IGZO film over the gate oxide film and exposed source; and
using at least one ALD process to perform an aluminum oxide (AlOx) deposition process to deposit an AlOx liner (channel passivation) over the IGZO.

9. The method of claim 8, wherein the heteroleptic In precursor utilizes alkyl and alkylamino (nitrogen-containing) ligands.

10. The method of claim 8, wherein the AlOx formation process comprises at least one AlOx liner deposition process using ALD with a strong oxidant at a wafer temperature ≤300° C. and at least one AlOx liner anneal process using a strong oxidant at a wafer temperature ≥300° C. and ≤500° C.

11. The method of claim 8, wherein the AlOx formation process comprises:
a first AlOx liner deposition process using ALD with a strong oxidant at a wafer temperature ≤300° C.;
a first AlOx liner anneal process using a strong oxidant at a wafer temperature ≥300° C. and ≤500° C.;
a second AlOx liner deposition process using ALD with a strong oxidant at a wafer temperature ≤300° C.;
a second AlOx liner anneal process using a strong oxidant at a wafer temperature ≥300° C. and ≤500° C.; and
a third AlOx liner deposition process using ALD with a strong oxidant at a wafer temperature ≥300° C. and ≤500° C.

12. The method of claim 1, wherein the vertical wordline driver supports a drive voltage of at least 30 volts.

13. A vertical wordline driver comprising:
a vertical transistor structure formed in a semiconductor substrate and comprising a gate all around (GAA) structure or a double-gate structure and including,
an outer member or wall comprising a gate oxide;
an IGZO (Indium Gallium Zinc Oxide) channel, adjacent to the gate oxide;
a channel liner, adjacent to the IGZO channel, comprising a high-κ material and forming a hermetically sealed IGZO channel of the vertical wordline driver; and
a dielectric fill material,
wherein the vertical wordline driver supports a drive voltage of at least 10 volts.

14. The vertical wordline driver of claim 13, wherein the vertical wordline driver supports a drive voltage of at least 30 volts.

15. The vertical wordline driver of claim 13, wherein vertical transistor structure comprises a conical frustrum shape with VWD CD≥WC CD or has straight sidewalls with VWD CD>WC CD or VWD CD=WC CD, where VWD is vertical wordline driver, WC is wordline contact, and CD is critical dimension.

16. The vertical wordline driver of claim 13, wherein the semiconductor substrate includes a plurality of stacked layers including a layer of polysilicon comprising a gate that is in contact with a portion of the gate oxide.

17. The vertical wordline driver of claim 13, wherein the channel liner comprises Aluminum oxide.

18. The vertical wordline driver of claim 13, wherein the vertical transistor structure is employed as a wordline driver in a three-dimensional (3D) NAND device.

19. A three-dimensional (3D) memory device, comprising:
a semiconductor substrate including a plurality of layers;
a plurality of wordlines formed in a 3D stack of multiple tiers;
a plurality of vertical wordline drivers, each comprising,
a vertical transistor structure formed in a semiconductor substrate and comprising a gate all around (GAA) structure or a double-gate structure including,
an outer member or wall comprising a gate oxide;
an IGZO (Indium Gallium Zinc Oxide) channel, adjacent to the gate oxide;
a channel liner, adjacent to the IGZO channel, comprising a high-κ material and forming a hermetically sealed IGZO channel;
a dielectric fill material;
an upper contact, electrically coupled to the hermetically sealed IGZO channel; and
a lower contact, electrically coupled to a respective wordline,
wherein the vertical wordline driver supports a drive voltage of at least 10 volts.

20. The 3D memory device of claim 19, wherein the 3D memory device comprises a 3D NAND memory device.

21. The 3D memory device of claim 19, wherein the plurality of layers in the semiconductor substrate includes a polysilicon layer that is in contact with the gate oxide and is used as a gate.

22. The 3D memory device of claim 19, wherein the vertical wordline driver supports a drive voltage of at least 30 volts.

23. The 3D memory device of claim 19, wherein the vertical transistor structure comprises a pillar having a conical frustrum shape with VWD CD≥WC CD or has straight sidewalls with VWD CD>WC CD or VWD CD=WC CD, where VWD is vertical wordline driver, WC is wordline contact, and CD is critical dimension.
